(19) United States
(12) Patent Application Publication
(10) Pub. No.: US 2012/0274197 A1
(43) Pub. Date: Nov. 1, 2012

(54) ENCLOSURE

(75) Inventors: BANG-WEI WANG, Shenzhen City (CN); ZHI-XIN LI, Shenzhen City (CN); JUN-XIONG ZHANG, Shenzhen City (CN); YOU-TAO WANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD ., Shenzhen City (CN)

(21) Appl. No.: 13/169,046

(22) Filed: Jun. 27, 2011

(30) Foreign Application Priority Data
Apr. 28, 2011 (CN) 201110108655.7

(51) Int. Cl. H05K 5/02

(52) U.S. Cl. 312/326

(57) ABSTRACT

An enclosure includes a main body, a bezel, and a pivot member pivotably attached the bezel to the main body. The pivot member is substantially U-shaped, thereby the bezel can be rotated relative to the main body in a wide range of angle.

### BACKGROUND

1. Technical Field

The present disclosure relates to enclosures and, more particularly, to an enclosure of an electronic device.

2. Description of Related Art

To install hard disk drives in electronic devices, such as servers, a bezel of the enclosure needs to be opened. Therefore, the bezel of an enclosure would better serve the procedure if it is rotatable through a wide range of angles.

### BRIEF DESCRIPTION OF THE DRAWINGS

Many aspects of the present embodiments can be better understood with reference to the following drawing. The components in the drawing are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a schematic view of an embodiment of an enclosure, showing a state of use when a bezel is open.

FIG. 2 is an exploded, isometric view of the enclosure of FIG. 1.

FIG. 3 is an enlarged view of a circled portion III of FIG. 2.

FIG. 4 is an assembled, isometric view of the enclosure of FIG. 1, but viewed from another perspective and showing a different state of use when the bezel is closed.

### DETAILED DESCRIPTION

The disclosure, including the accompanying drawing, is illustrated by way of examples and not by way of limitation. It should be noted that references to “an” or “one” embodiment in this disclosure are not necessarily to the same embodiment, and such references mean at least one.

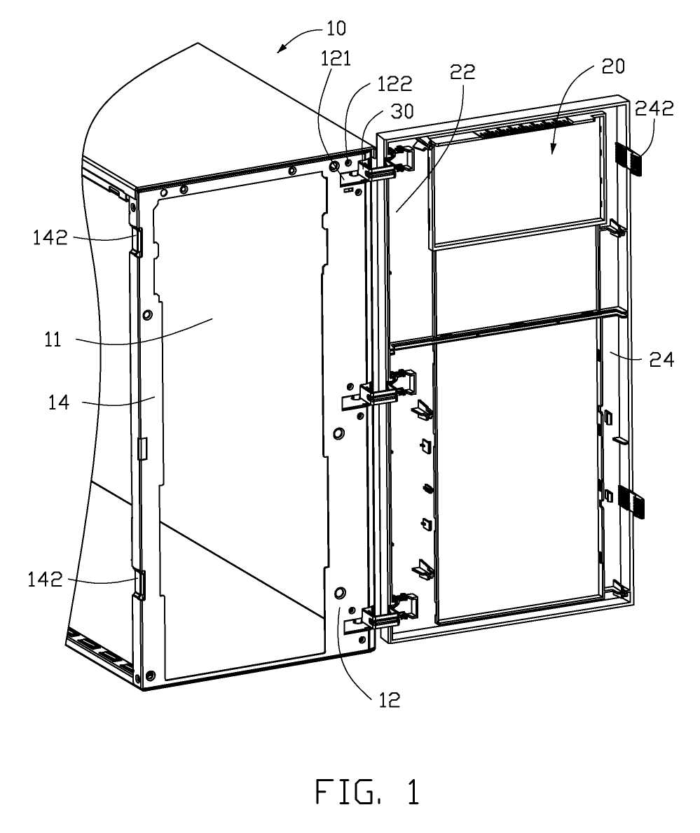

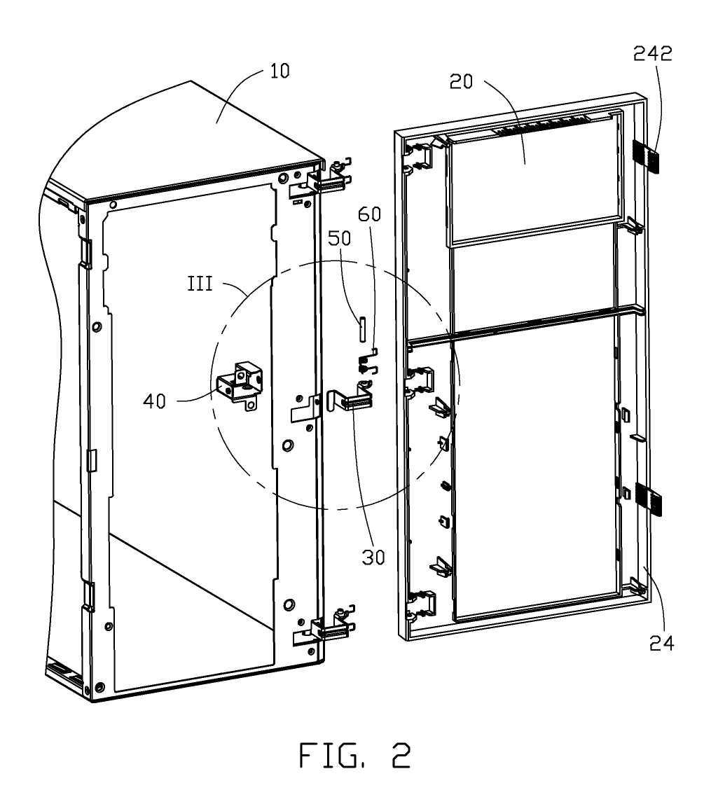

Referring to FIG. 1 and FIG. 2, an exemplary embodiment of an enclosure includes a main body 10, a bezel 20, three pivot members 30, three mounting members 40, three shafts 50, and three resilient members 60.

The main body 10 is substantially box-shaped, and includes a front plate 14, an opening 11 defined through the center of the front plate 14.

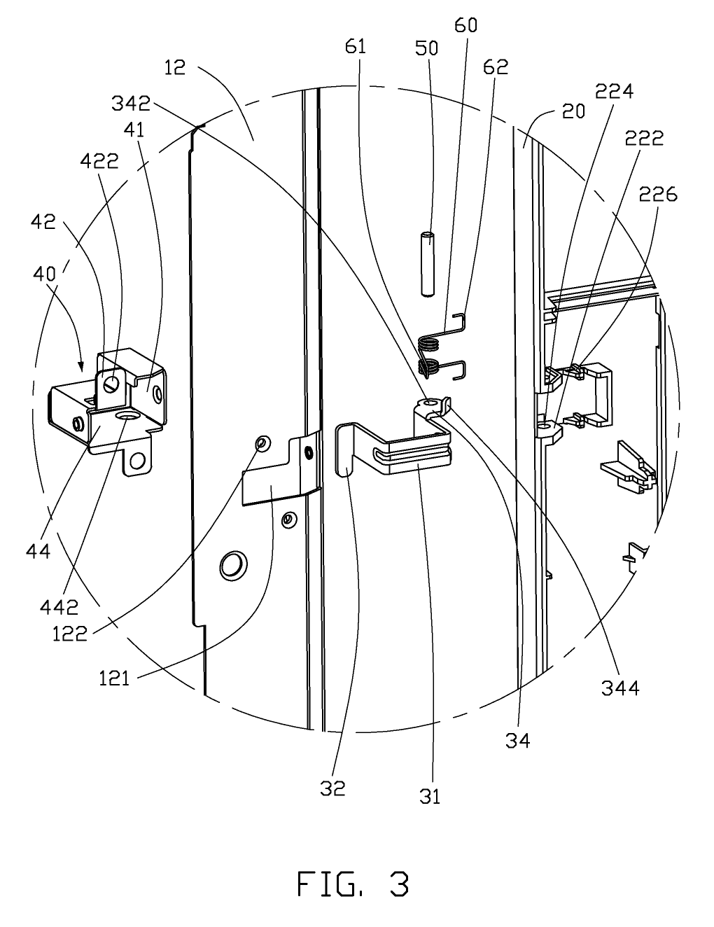

Referring to FIG. 3, the front plate 14 defines three through holes 121 in a first side 12 of the front plate 14 from top to bottom. Two mounting holes 122 are also defined in the first side 12, respectively above and below each through hole 121.

Two locking portions 142 are formed on a second side of the front plate 14, opposite to the first side 12, from top to bottom.

The bezel 20 includes a pivot side 22, and a locking side 24 opposite to the pivot side 22. Two parallel pivot portions 222 are formed on the pivot side 22, corresponding to each through hole 121. A pivot hole 224 is defined in each pivot portion 222. A rod 226 protrudes from the pivot side 22, adjacent to each pivot portion 222. Two spaced hooks 242 are formed extending from the locking side 24.

Each pivot member 30 includes a substantially U-shaped base 31. An inserting portion 32 extends down from a first distal end of the base 31. Two parallel connecting portions 34 extend out from a second distal end of the base 31. Each connecting portion 34 defines a connecting hole 342. A tab extends from a side of each connecting portion 34, opposite to the other connecting portion 34.

Each mounting member 40 is a substantially L-shaped box and defines an L-shaped receiving space 41. Two mounting pieces 42 are formed from the mounting member 40 beside the receiving space 41. A mounting hole 422 is defined in each mounting piece 42. The mounting member 40 defines a pivot hole 442 in a bottom 44 of the mounting member 40, communicating with the receiving space 41.

In this embodiment, each resilient member 60 is a torsion spring and includes an engaging portion 61 at a middle portion and two fingers 62 at opposite ends of the resilient member 60.

In assembly, the bezel 20 is pivotably mounted to the main body 10 using the pivot members 30. The assembly process of only one of the pivot members 30 is described as an example. The mounting member 40 is fixed to an inner surface of the front plate 14 through the mounting pieces 42 being screwed to the first side 12. The receiving space 41 aligns with the through hole 121. The connecting portions 34 are arranged between the pivot portions 222. The connecting holes 342 align with the corresponding pivot holes 224. The shaft 50 extends through one of the pivot holes 224, the connecting holes 342, and the other pivot hole 224. The resilient members 60 are arranged between the connecting portions 34 and set around the shaft 50. The engaging portion 61 resists against the base 31. The fingers 62 resist against the bezel 20 and are positioned by the rods 226, respectively. The inserting portion 32 extends through the receiving space 41 and is pivotably inserted in the pivot hole 442.

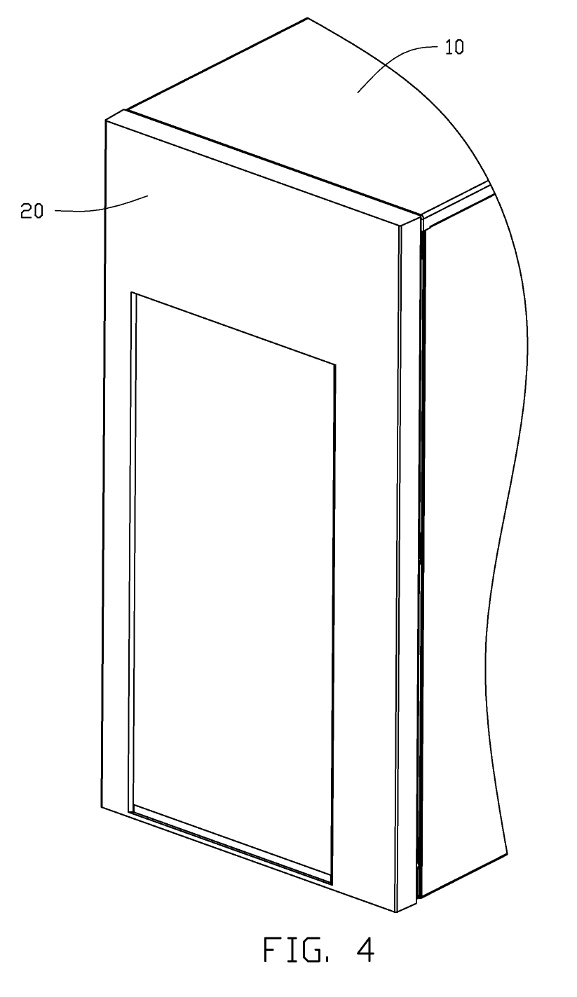

Referring to FIG. 4, to close the bezel 20 relative to the main body 10, thereby covering the opening 11, the bezel 20 is pivoted, with the locking side 24 of the bezel 20 moved to the front plate 14 of the main body 10. The hooks 242 latch the locking portions 142. During the above process, the base 31 extends through the through hole 227.

In this embodiment, the pivot members 30 are substantially U-shaped to allow rotation of the bezel 20 relative to the main body 10 through a wide range of angles.

It is to be understood, however, that even though numerous characteristics and advantages of the embodiments have been set forth in the foregoing description, together with details of the structure and function of the embodiments, the disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. An enclosure comprising:
a main body comprising a front plate;
a bezel comprising a pivot side, two pivot portions extending from the pivot side;
a mounting member fixed to the front plate of the main body, and defining a pivot hole; and
a pivot member comprising a substantially U-shaped base, wherein an inserting portion is formed from a first distal end of the base, two connecting portions are formed from a second distal end of the base;
wherein the connecting portions are pivotably connected to the pivot portions of the bezel, the inserting portion is pivotably inserted in the pivot hole of the mounting member.

2. The enclosure of claim 1, wherein the main body defines an opening, the mounting member is located at a first side of the opening.

3. The enclosure of claim 2, wherein the front plate forms a locking portion at a second side of the opening, the bezel further comprises a locking side, the locking side comprising a hook capable of engaging with the locking portion.

4. The enclosure of claim 1, wherein a connecting hole is defined in each of the connecting portions of the pivot member, a pivot hole is defined in each of the pivot portions, the connecting portions of the pivot member are arranged between the pivot portions, with the connecting holes aligning with the pivot holes of the pivot portions, a shaft pivotably extends through the connecting holes and the pivot holes.

5. The enclosure of claim 4, further comprising a resilient member arranged between the connecting portions and set around the shaft, wherein the resilient member comprises an engaging portion and two fingers, the engaging portion resists against the base of the pivot member, the fingers resist against the bezel.

6. The enclosure of claim 5, wherein two rods extend on the bezel, adjacent to the pivot portions, the fingers of the resilient member resist against the rods, respectively.

7. The enclosure of claim 1, wherein the front plate of the main body defines a through hole, the mounting member defines a receiving space aligning with the through hole, the pivot hole is defined in a bottom of the mounting member and communicates with the receiving space, the inserting portion of the pivot member extends through the receiving space of the mounting member to be inserted in the pivot hole of the mounting member.

8. An enclosure comprising:
a front plate;
a bezel comprising a pivot side;
a mounting member fixed to an inner surface of a first side of the front plate, and defining a pivot hole; and
a pivot member comprising a base, wherein an inserting portion is formed from a first distal end of the base and pivotably inserted in the pivot hole of the mounting member, a second distal end of the base is pivotably mounted to the pivot side of the bezel.

9. The enclosure of claim 8, wherein the mounting member further defines a receiving space communicating with the pivot hole, the front plate defines a second through hole aligning with the receiving space of the mounting member, the inserting portion of the pivot member extends through the receiving space of the mounting member to be pviotably inserted in the pivot hole of the mounting member.

10. The enclosure of claim 8, wherein the base is the pivot member is substantially U-shaped.

11. The enclosure of claim 8, wherein the front plate forms a locking portion at a second side of the opening, the bezel further comprises a locking side, the locking side comprising a hook capable of engaging with the locking portion.
